(19) United States
(12) Patent Application Publication
(10) Pub. No.: US 2004/0000844 A1
(43) Pub. Date: Jan. 1, 2004

(54) Low profile temperature-compensated low-stress crystal mount structure

(76) Inventors: Peter E. Morley, Amherst, NH (US); Daniel S. Stevens, Stratham, NH (US)

Correspondence Address: MAINE & ASMUS, 100 MAIN STREET, P O BOX 3445, NASHUA, NH, 03061-3445, US

(21) Appl. No.: 10/610,203

(22) Filed: Jun. 30, 2003

Related U.S. Application Data
(60) Provisional application No. 60/392,805, filed on Jun. 28, 2002.

(51) Int. Cl. H01L 41/053

(52) U.S. Cl. 310/348

(57) ABSTRACT

A temperature compensated mounting structure, such that the stress applied to the resonator element by the mounting is minimized over a wide range of temperatures. This compensation significantly reduces or eliminates residual stresses from earlier process stages, such as cement curing, as well as stresses induced by ambient temperature changes. The entire structure is designed to be stress-free by the selection of materials and the dimensions of the elements. The geometry of the structure and the choice of materials are selected based on their linear and higher order expansion coefficients so as to minimize the forces between the resonator element and the mount resulting from temperature changes.

### RELATED APPLICATIONS

This application claims the benefit of U.S. Provisional Application No. 60/392,805 filed Jun. 28, 2002, which is herein incorporated in its entirety by reference. A related application, entitled LOW ACCELERATION SENSITIVITY MOUNTING STRUCTURES FOR CRYSTAL RESONATORS Ser. No. 10/446522 is incorporated by reference for all purposes.

### FIELD OF THE INVENTION

The present invention relates to a packaging mount with thermal compensation, and more specifically, to a mounting arrangement for resonators that minimizes effects due to thermal expansion.

### BACKGROUND OF THE INVENTION

As is well known in the field of frequency control, crystal resonators are used for providing highly precise reference frequencies or frequency sources. However, crystal resonators can be sensitive to stresses resulting from, for example, temperature variation. One important goal of resonator mount design is to keep the stress low and constant over time.

A typical precision resonator is mounted using clips. The clips are usually flexible and, as a result of their compliance, there is some amelioration of the stresses caused by the differential thermal expansion coefficients of the elements of the package and the crystal.

In a typical package, there is a package floor with electrically conductive terminations extending to the outside. Flexible metal clips are connected from the post to the crystal and they retain the crystal in position as well as providing electrical connection. The clips are flexible and can be bent in a variety of ways. The clips are typically metal and conductive, and the resonator element is affixed to the clips. A further description of resonator mount packages is provided by commonly assigned U.S. Pat. No. 5,917,272, which is incorporated by reference herein.

Stresses between the mount structure and the resonator can induce relatively unpredictable frequency fluctuations. Temperature induced stresses can be caused by the differential thermal expansion coefficients between the various materials. Externally applied forces, including the effect of barometric pressure changes can also apply stresses to the resonator element.

In conventional mounting configurations, the header is typically made of glass, together with a material such as Kovar, which is expansion-coefficient matched to the sealing glass to provide a hermetic enclosure. The clips that connect the header and the resonator are made of a variety of materials, such as nickel or stainless steel. In either case, the thermal expansion coefficient of the quartz disc will not be precisely matched to that of the base assembly.

The crystal manufacturing processes usually involves high temperature operations, such as adhesive curing, so when the assembly cools, this expansion coefficient mismatch results in residual stress applied to the resonator disc. This in turn can lead to long term frequency aging due to stress relaxation with time.

Temperature changes during normal use also give rise to stresses, which cause, in turn, frequency retrace and undesirable hysteresis effects. This effect is particularly severe when the crystal mounting clips are stiff and also short in comparison with the rest of the assembly.

Another factor that causes undesirable changes in resonator frequency in conventionally packaged resonators is the result of changes in external barometric pressure. Such barometric changes can cause some minor deformations in the header, which then cause stresses between the mount and the resonator plate. This in turn causes a frequency change.

Many precision oscillator applications have a need for crystals with low profile packages. Prior art mounting systems attempt to lower packaging profile by making the clips shorter and shorter. However, such shortened clips are very stiff and do not provide adequate compliance, and thus performance is degraded.

There are existing systems that allow sufficient flexibility and retain the crystal by longer clips. These clips are not typically consistent with a low profile. In addition, mechanical stresses on the clips are transmitted directly to the resonator.

Conventional crystal mounts have at least two basic forms. In the first, the crystal blank is mounted with its face perpendicular to the package terminations, and long mounting clips to attach the resonator plate. The mounting clips are in the plane of the crystal but are not symmetrical. Typically only two clips are utilized. Examples of this form of holder, whose bases are typically oval in shape, are the cold-welded types HC47/U, HC43/U and HC45/U. Prior art design of FIG. 3 illustrates a mounting configuration that is incorporated into the package known in the field as HC37/U. In this design, the resonator is held perpendicular to the ceramic substrate and retained by the longer clips, which reduces the stress, but increases the package profile.

FIG. 2 shows another prior art configuration in which the crystal clip takes a variety of forms. In this type of configuration there are generally four clips used. The resonator is held parallel to the base and the clips keep the resonator in place with the normal of the crystal face parallel to the terminations. Examples of this form of holder, which are typically circular, are the cold-welded types HC40/U, HC37/U and HC35/U. Because of the possibility of four mounting points and the short length of the mounts, the circular styles are particularly suited to low profile applications and to situations where the environmental conditions are harsh. Examples of this form of holder, which are typically circular, are the cold-welded types HC40/U, HC37/U and HC35/U. In general, 2, 3, or 4 mounting clips are utilized. In low profile applications the clips are typically shorter in length and therefore sacrifice some compliance.

Thus, prior art low profile packages can be significantly limited in their achievable performance. Other prior art systems have varied the composition of the clips in order to reduce length and maintain the mechanical compliance. However, despite all the efforts and variations of the prior art, prior art packaging systems have difficulty in balancing the trade off between a smaller profile and performance with respect to temperature-induced stresses and mounting clip compliance.

There have been many attempts to alleviate the aforementioned problems. In U.S. Pat. No. 4,406,966 ('966) there is a temperature compensated system that uses a spring or bellows support to connect to the resonator. The flexible bellows or springs have a coefficient of thermal expansion that is different than that of the resonator. This system requires adding additional components to the package and adding complexity. There would be no possibility of making a compact low profile package with the '966 patent.

In U.S. Pat. No. 3,828,210, there is a mounting structure designed for housing one or more crystal plates. The housing has upper mount tabs that are ‘L’ shaped to provide some resiliency for thermal expansion because the connection is at the leg of the tab. Another patent disclosing temperature compensation is U.S. Pat. No. 4,985,655 ('655). The '655 patent describes a washer sandwiched between the lower housing and the package base that absorbs some portion of the thermal expansion.

A surface acoustic wave (SAW) device is described in U.S. Pat. No. 5,712,523 that uses differing thermal expansion coefficients for the SAW element, the support substrate, and the conductive cap. This invention takes into account the temperature fluctuations and structures the package to account for the temperature changes.

The temperature insensitive mounting described in U.S. Pat. No. 4,430,596 discloses using pedestals located at optimal points, or axes in the X-Z plane of the crystal that are less sensitive to stresses. The axes at 60 degrees, 120 degrees and 240 degrees and 300 degrees were found to be insensitive to stresses generated in the crystal by thermal expansion of the substrate and crystal.

There are also prior art devices that use the physical properties and linear expansion coefficients to provide a more stable configuration. One of the early examples is the Harrison compensated pendulum that was used in early chronometers to keep accurate time independent of ambient temperature.

The mounting structures for other devices such as optics have experimented with incorporating the thermal compensation principles into the designs. A compensated optical head for a laser scanner is shown in U.S. Pat. No. 5,255,015, a lens mounting with temperature adjustments is illustrated in U.S. Pat. No. 4,460,245, and a temperature compensated interferometer is discussed in U.S. Pat. No. 4,765,741.

Despite all the attempts in the prior art, there continues to be a need for improvement in low profile packaging of resonator elements without sacrificing performance. What is needed is a means for mounting the resonator without using long clips. The mounting should permit the resonator to be laid parallel to the header for low profile mounting, yet preserve the stress absorbing qualities of the conventional mounts. The preferred embodiment should allow the use of existing packaging techniques in order to aid in manufacturing.

### BRIEF SUMMARY OF THE INVENTION

Accordingly, an object of the present invention is a temperature compensated mount such that the crystal mount structure is temperature compensated and the whole structure including the clips, joints, and ceramic base are stress free.

One embodiment of the invention is a temperature compensated mounting package, comprising a base element having a base thermal expansion coefficient M₁, with a resonator having a resonator thermal expansion coefficient M₂, wherein L₃ is an approximate distance from a midpoint of the resonator to an outer edge of the resonator. There are at least two clips each having a clip thermal expansion coefficient M₃, wherein the clips are coupled to the resonator at the outer edge and coupled to the base at a base connection. The thermal expansion coefficient M₁, M₂, and M₃, the dimension L₃, and a location of the base connection are designed such that a residual stress of the package is zero.

Another variation includes a thermal stress-free mounting structure, comprising a base element having a base thermal expansion coefficient M₁, a substantially planar resonator having a resonator thermal expansion coefficient M₂, wherein L₃ is an approximate distance from a midpoint of said resonator to an outer edge of said resonator. There are at least two clips each having a clip thermal expansion coefficient M₃, wherein the clips are coupled to the resonator at the outer edge and coupled to the base at a base connection. And, there is a means for calculating the stress-free structure, wherein the means comprises processing according to the M1, M₂, M₃, L₃ and placement of the clips.

An object of the invention includes a method of choosing geometries, lengths and materials for the mount and substrate so that the changes in temperature give little or no net stress effects on the resonator. In other words, combining the physical properties in such a manner that there is equilibrium in the mounting system.

One of the objects of the present invention is dimensional stability and maintenance of zero stress applied to the crystal. A temperature compensated crystal mounting scheme is described such that the stress applied to the resonator element by the mounting structure is minimized over a wide range of temperatures. This compensation significantly reduces residual stresses from earlier process stages, such as cement curing, and material creep is not a factor in stress relaxation.

This compensation is achieved by careful choice of materials, dimensions and resonator orientation. The geometry of the structure and the choice of materials are selected based on their linear expansion coefficients so as to minimize the lateral forces between the resonator element and the mount resulting from a temperature change.

Also considered is the orientation of the resonator element, which may, as is the case with quartz, have anisotropic thermal expansion properties in the plane of the resonator.

The mounting structure described herein addresses the problem of residual stress resulting from thermal expansion mismatches, and also provides a possibility for a low-profile configuration. The substrate material, clip material, mounting geometry and crystal orientation are all chosen so that their respective expansion coefficients are compensated by the structure. In the case of anisotropic thermal coefficient of expansion (TCE), it is apparent that the clips and the mounting points will differ in different directions.

Objects and advantages of the new mounting structure include an insensitivity to changes in temperature. These temperature changes can be associated with stages in the manufacturing process, or with changes in ambient conditions.

Additional goals of the present invention are to achieve a lower long-term aging rate, lower frequency hysteresis and less retrace effect than with conventional mounting configurations.

Points of novelty include the concept of using a selection of different materials in a crystal mount structure to achieve thermal expansion compensation. In addition, the various mount geometries, configurations, and thermal dimensional stability schemes employed herein are applicable to other technological applications.

Still other objects and advantages of the present invention will become readily apparent to those skilled in this art from the following detailed description. As will be realized, the invention is capable of other and different embodiments. The invention's several details are capable of modification in various respects without departing from the spirit of the invention.

### BRIEF DESCRIPTION OF THE DRAWINGS

The present invention will be readily understood by the following detailed description in conjunction with the accompanying drawings, wherein like reference numerals designate like structural elements:

FIG. 1 side view perspective of the clips for mounting the resonator and showing the perspective view of the elements;

FIG. 2 prior art HC37/U mounting configuration showing the resonator mounted parallel;

FIG. 3 prior art HC47/U mounting configuration showing the resonator mounted perpendicular to the base

FIG. 4 planar mounting configuration with shelf and expanded mount clips

### DETAILED DESCRIPTION OF THE INVENTION

The present invention is based upon the understanding that all the prior art devices were unable to adequately address the aforementioned problems.

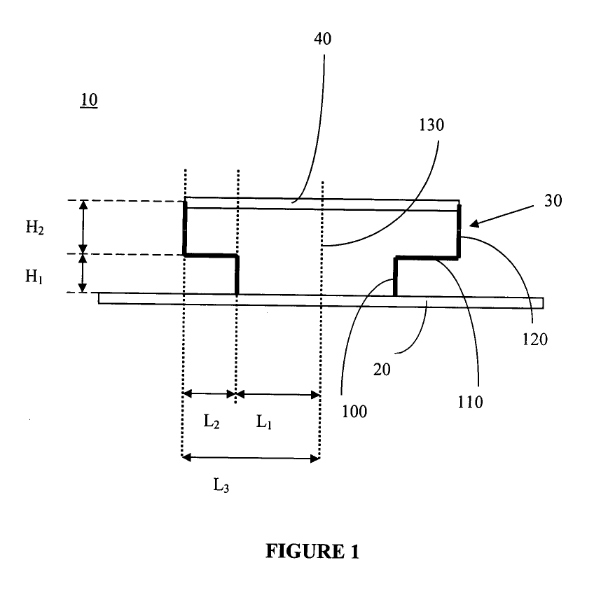

Referring to FIG. 1, a low profile package 10 is illustrated, wherein a base or substrate 20 of material M₁ is shown substantially parallel to a resonator of material M₃. And, there are two or more mounting clips 30 of material M₂ that extend from the substrate 20, wherein the clips 30 attach to the outer edge of the resonator 40 at a mounting point 50. The mounting point 50 is typically an adhesive binding the clip to the outer edge of the resonator, although other attachment means are within the scope of the invention.

The resonator has an axis of symmetry 130 representing the center or midpoint of the resonator for this axis. L₃ is the length from the axis of symmetry 130 to the outer edge of the crystal 40. Thus, the total length of the resonator along this axis is 2×L₃. The effects relating to the thickness and properties of the adhesive used at the mounting point 50 are usually negligible. And, the properties of the mounting clips 30 are factored into the equilibrium such that they are already accounted for in the present invention.

The various elements are generally of different materials. The substrate material M₁, the mount material M₂ and the resonator material M₃ will therefore have differing thermal expansion coefficients. One of the features of the present invention is to utilize these differing thermal expansion properties of the materials to essentially eliminate or minimize the overall thermal stress effects. In a preferred embodiment, this is accomplished by analyzing the geometry of the mounting and the thermal properties of the various materials, and calculating the clip arrangement to minimize stress on the resonator 40. Although in this embodiment the arrangement of the clips 30 are adjusted according to the properties of the materials, it is also within the scope of the invention to process for any of the variables to produce a mounting structure as described herein.

In one embodiment the mounting clips 30 are an integral member of material M₂ and have a first section 100 connecting perpendicular to the substrate 20 on a first end and substantially perpendicular to a second section 110 on a second end. The second section 110 is approximately parallel to the substrate 20 and extends outwards to the outer edge of the resonator 40. The third section 120 connects perpendicularly from the end of the second section 110 and extends perpendicularly to mate with the outer edge of the resonator 40 at the mounting point 50. A suitable small ledge or shelf (not shown) could be incorporated at mounting point 50 to facilitate assembly and may be used in conjunction with an adhesive (not shown).

The designation of the mounting clips 30 in sections 100, 110, 120 is included to show that while in most embodiments the clips would be of a unitary material having uniform thermal properties, it is also within the scope of the present invention to have sectionalized clips of different materials. For example, the mounting section 120 that connects to the resonator can be of a different material and shape. The thermal properties of the differing materials would be factored into the formulation to calculate the placement of the mounting clip onto the substrate 20. There may also be other elements such as adhesives, solder/epoxy, posts and ledges/shelves that may be accounted for in the processing if the thermal properties are known. Furthermore, the base 20 may include various additional surfaces or structures that may require inclusion of the thermal properties of these surfaces or structures to properly eliminate the stress components.

The choice of materials and the orientation/geometry of the mounting structures are aspects of the design considerations. Once the thermal considerations have been calculated, the important dimensions with respect to the mountings 30 is L3 (one-half the length of the resonator) and the placement of the clip 30 onto the substrate 20, which is located at L₃−L₂ or L₃−L₁, wherein L₁+L₂=L₃. In this embodiment the resonator and the substantially planar and measurements are referenced from the axis of symmetry 130.

The heights of the clip sections, H₁ and H₂ are not important in the overall end result for the stress-free structure 10. In most commercial applications the height is a factor and generally the lower profile designs are more useful in electronics with space constraints.

To achieve temperature compensation for this embodiment of opposing clips, the lengths of the various elements can be calculated by the following formula:

L₁=L₃(M₃−M₂)/(M₁−M₂)

where M₁, M₂ and M₃ are the linear thermal expansion coefficients of the substrate, clip and resonator respectively. This relationship could in principle be further refined to include higher order thermal expansion characteristics of the materials by the use of the use of the higher order expansion coefficients, which could be useful to minimize residual stresses caused by TCE mismatches that occur due to relatively high assembly temperatures.

The following tables show the typical thermal expansion coefficient properties in the linear region at around 20° C. of some of the typical elements that are used in designing and calculating the optimal operating conditions of the resonator mounting. Material properties of quartz are shown, as this is the most usual material for precision resonator manufacture, but the principle could be equally applied to any resonator material. Note that the quartz is anisotropic and the properties, such as the thermal expansion coefficients, vary with the crystallographic direction. Likewise, the cut may also influence the properties of the crystal. The typical thermal expansion coefficients are shown for the linear region at an approximate temperature of 20° C.

TABLE A
thermal expansion coefficients of the quartz resonator in the linear region

| Material | direction | Linear Thermal expansion coefficient |
|---|---|---|
| Quartz | X | 13.7 ppm/° C. |
| Quartz | Z | 7.4 ppm/° C. |
| Quartz AT | Z' | 9.5 ppm/° C. |
| Quartz SC | Z' | 9.5 ppm/° C. |

TABLE B
thermal expansion coefficients of the materials for the
clips and base in the linear region

| Material | Linear Thermal expansion coefficient |
|---|---|
| Al₂O₃ | 6.7 ppm/° C. |
| Cu | 17.0 ppm/° C. |
| Ni | 13.4 ppm/° C. |
| Ag | 18.8 ppm/° C. |
| Mo | 4.8 ppm/° C. |
| 3O4 stainless steel | 17.3 ppm/° C. |
| Al | 23.1 ppm/° C. |
| Au | 14.2 ppm/° C. |
| AlN | 4.5 ppm/° C. |

As an example, if the substrate is made from alumina ceramic, the typical expansion coefficient is about 6.7 ppm/° C. In this example, the resonator is quartz, and the expansion coefficient for crystalline quartz is anisotropic, with values of 13.7 ppm/° C. in the X direction and for AT cut quartz, 9.5 ppm/° C. in the Z′. To achieve temperature expansion compensation, the clip material therefore needs to have a higher expansion coefficient than quartz, and several materials fit this criterion. Stainless steel type 304 has a 17.3 ppm/° C. expansion coefficient.

Choosing, for example, a length for the resonator so that L₃=7.5 mm, using an alumina ceramic substrate, AT-cut quartz resonator and stainless steel 304 clips, the length of the clip in the horizontal plane is given by:

L₁=L₃(M₃−M₂)/(M₁M₂)

In this case,

L₁=7.5 (9.5−17.3)/(6.7−17.3)=5.5 mm and

L₂=L₃−L₁=7.5−5.5=2.0 mm

Thus, the mount clip is placed 5.5 mm from the center point or axis of symmetry 130 of the resonator, or 2.2 mm from the outer edge.

Higher order coefficients, those in the non-linear range, also can be used to satisfy the stress-free design properties described herein although the calculations may require empirical testing or some operating temperature range to determine the properties of the materials in the non-linear region.

The shape of the clips as depicted in FIG. 1 is merely for illustrative purposes, and other designs and shapes are within the scope of the invention.

While the illustrated embodiment shows a 2-point mounting structure, the present invention works equally well with any number of clips mountings. For example, a 4-point orthogonal mounting utilizes the same calculations and renders the same results as the 2-point mounting.

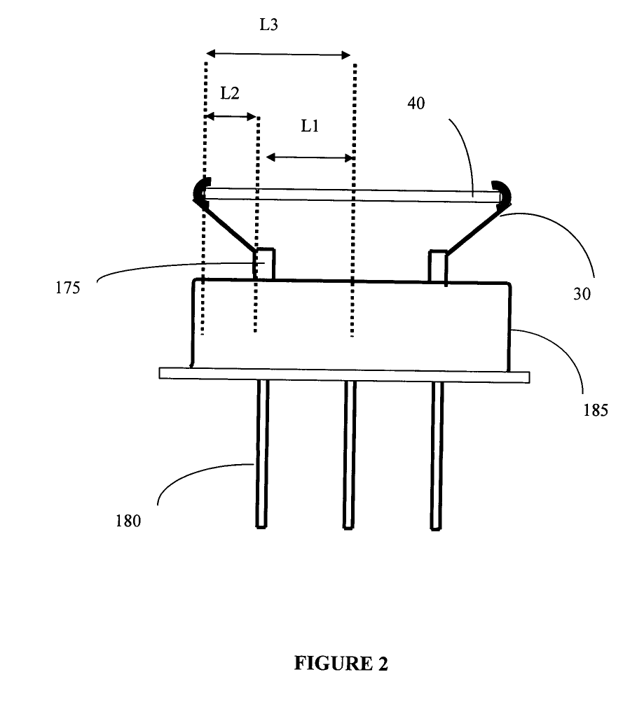

Referring to FIG. 2, a perspective view of a 2-point HC37/U mounting structure is illustrated. The package is shown as a circular TO-X style assembly with rigid posts 175 for attaching the mounts 30. The resonator element 40 is shown suspended between the mounting clips 30. This embodiment may or may not utilize adhesive, solder or epoxy.

The electrical leads 180 connect through the base 185, typically kovar/glass, to the mounting clips 30. The clips 30 retain the resonator 40 in position above the kovar/glass base 185 with a combination of vertical and horizontal forces. One of the clips 30 may be coupled to the top electrode (not shown) of the resonator 40, while opposing clip 30 connects to the bottom electrode (not shown). Other methods of electrical connectivity are known in the art, such as wire jumpers. As shown, the resonator 40 is held at two points by two angular clips 30 that extend upwardly and angularly from the rigid posts 175. The thermal properties of the posts 175 may be non-negligible and require inclusion in the calculations.

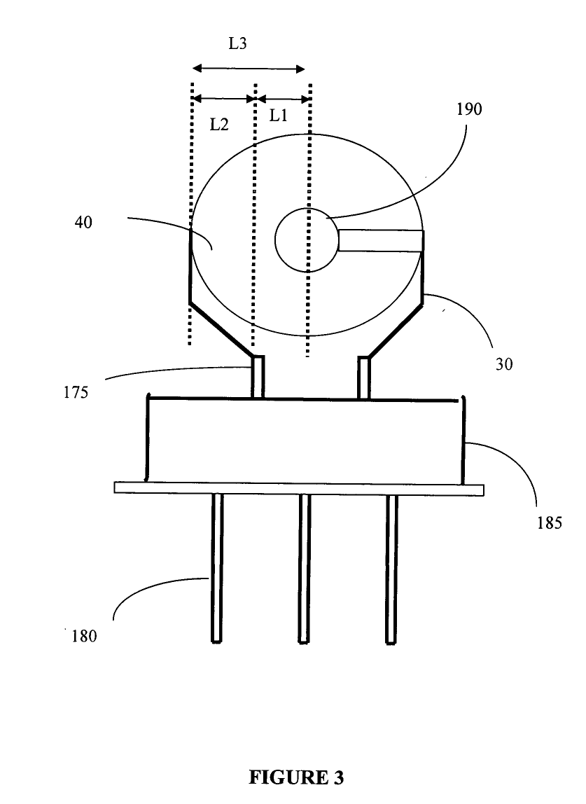

Another prior art mounting configuration is shown in FIG. 3, a perspective view of a 2-point HC47/U mounting structure is illustrated. The package is shown as an oval base assembly with rigid posts 175 for attaching the mounts 30. The resonator element 40 is shown suspended between the mounting clips 30 in a perpendicular manner.

The electrical leads 180 connect through the base 185 to the mounting clips 30. The clips 30 retain the resonator 40 in position above the kovar/glass base 185 with a combination of vertical and horizontal forces. One of the clips 30 is coupled to the one electrode 190 of the resonator 40, while opposing clip connects to the other electrode (not shown). As shown, the resonator 40 is held at two points by two angular clips 30 that extend upwardly and at an angle from the rigid posts 175.

In the embodiments of FIG. 2 and FIG. 3, the stress-free structure design according to the teachings of the present invention would be the same as described herein, with the addition of incorporating the thermal expansion properties of the rigid posts 175. However, as known in the art, the post and base are generally matched thermally so that the effects would be negligible and can be ignored.

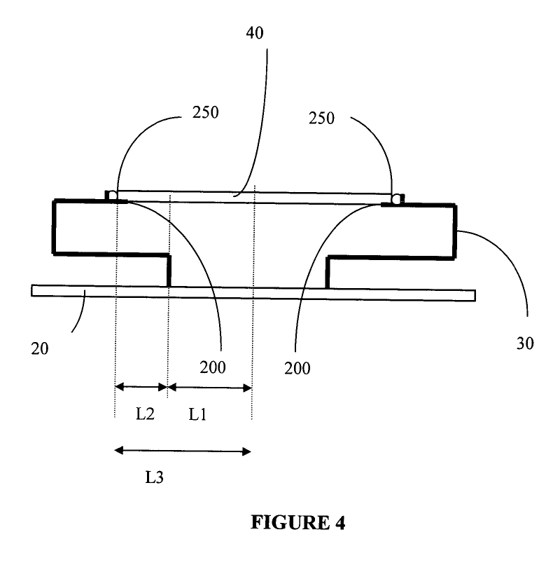

Referring to FIG. 4, the resonator mounting structure is depicted with certain variations. While the base 20 of material M₁, mounts 30 of mount material M₂ and the resonator 40 of material M₃ are still selected as described herein, this embodiment illustrates the adhesive, solder or epoxy 250 that is coupled between the resonator 40 and the mount 30. While the effects of the adhesive 250 or other compound will generally be negligible, certain applications may require factoring in the thermal expansion coefficients of the adhesive into the calculations. This is especially applicable if a large sized adhesive/solder was used or if the properties of the adhesive/solder were of a particular concern that warranted inclusion.

Also noted in FIG. 4 is the extension of the mount 30 beyond the outer edge of the resonator 40. The extra length of the mount clips does not affect the stress-free status or equilibrium of the overall structure. This embodiment also shows a ledge 200 on the mount 30 to allow a surface for the resonator 40 to be held in place. The presentation of the clips 30 as several generally straight lengths is for illustrative purposes, and the actual shape can be bulbous or arcuate as well as any other shape as would be known to those skilled in the art.

Other combinations are well within the scope of the invention and anticipated by the present invention. For example, there are many emerging piezoelectric materials that are highly applicable to the manufacture of precision resonators. For example, the present invention is applicable to Surface Acoustic Wave (SAW) devices, Bulk Acoustic Wave (BAW) devices, and the Langasite family of resonators. BAW sensors use the same quartz element as used in precision timing applications although generally used for monitoring environmentally or chemically altered frequency changes. Thus, in addition to quartz, materials of common interest for acoustic wave devices include, but are not limited to, Gallium Othrophosphate, Lithium Tetraborate, Lithium Niobate, Lithium Tantalate, and members of the Langasite family.

The clips have been illustrated in one embodiment herein, coupling from the base to the outer edge of the resonator, wherein the resonator is coupled to the clips via adhesive. Various other means for coupling from the clips to the resonator are described in the incorporated references. The electrical connections that couple to the top and bottom electrodes have not been illustrated, as it well known to those skilled in the art. The various posts, adhesives, solder or epoxy may or may not have thermal properties that would affect the stress-free design of the package herein, but it is within the scope of the present invention to account for any of the variables that contribute thermal expansion into the structure.

As described in the related application entitled LOW ACCELERATION SENSITIVITY MOUNTING STRUCTURES FOR CRYSTAL RESONATORS Ser. No. 10/446,522, the quartz plate azimuthal orientation can also be chosen to minimize the force-frequency effect to further reduce the effects of any remaining force from the mount on the crystal frequency. The substrate can be mounted on a conventional header, or can itself be a part of a package structure. The azimuthal orientation refers to the angular placement of the clips along the resonator chosen to optimize the acceleration sensitivity according to the choice of crystal cut angle. The advantages of varying the angle mounting position results in reduced frequency changes due to the force-frequency effect.

As described in the pending application referenced herein, depending upon the quartz material, the crystal orientation can be cut in different directions and get different properties. One of these properties deals with how well stress is coupled into the resonator by applied stress and influenced by the mount locations on the resonator. For example, an SC resonator can be analyzed by probes and the frequency response can be measured. At certain location there is no change in frequency response, and these locations are called the zeros. For SC cuts there are two sets of zeros that are about 90 degrees apart. For AT cut crystal the spacing between the sets of zeros is about 60 degrees and about 120 degrees. The mount is rotated to the ‘sweet spot’ in order to take advantage of the zeros.

In one application the mount is configured such that thermal forces applied across the resonator element are temperature compensated. One variation of the present invention comprises an Alumina ceramic substrate, an arrangement for mounting using the thermal principles, and a quartz material or other piezoelectric as the resonator. Each of the constituent materials has linear thermal expansion coefficients that differ. By analyzing the expansion coefficients of the various materials and the physical dimensions and characteristics of the mounting system, the present invention teaches the methods for processing the choices of materials and structures to develop a thermally compensated package assembly.

As detailed herein, the resonator manufacturing process includes assembling at a high temperature (typically between 160° C. and 300° C.) at which point the adhesive cures. In a typical crystal resonator, when the adhesive cools down, the differing material expansion coefficients will cause residual stresses. Such stresses are eliminated by the design of the present invention.

The present invention has been particularly shown and described with respect to certain preferred embodiments of features. However, it should be readily apparent to those of ordinary skill in the art that various changes and modifications in form and details may be made without departing from the spirit and scope of the invention. The drawings and description are to be regarded as illustrative in nature, and not as restrictive.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

What is claimed is:

1. A temperature compensated mounting package, comprising:
a base element having a base thermal expansion coefficient M₁;
a resonator having a resonator thermal expansion coefficient M₂, wherein L₃ is an approximate distance from a midpoint of said resonator to an outer edge of said resonator;
at least two clips each having a clip thermal expansion coefficient M₃, wherein said clips are coupled to said resonator at said outer edge and coupled to said base at a base connection;
and wherein said thermal expansion coefficient M₁, M₂, and M₃, said dimension L₃, and a location of said base connection are designed such that a residual stress of said package is zero.

2. The temperature compensated package according to claim 1, wherein said crystal is substantially parallel to said base, and wherein L₁ is an approximate distance from said midpoint of said resonator to said base connection, and wherein a placement of said base connection is determined by L₁=L₃ (M₃−M₂)/(M₁−M₂).

3. The temperature compensated package according to claim 1, wherein said clips are coupled to said resonator by an element selected from the group comprising: adhesive, solder and epoxy.

4. The temperature compensated package according to claim 3, wherein a thermal expansion property of said element is included in designing said package wherein said residual stress is zero.

5. The temperature compensated package according to claim 1, further comprising a shelf.

6. The temperature compensated package according to claim 1, further comprising an element selected from the group comprising a clip shelf and a post.

7. The temperature compensated package according to claim 6, wherein a thermal expansion property of said element is included in designing said package wherein said residual stress is zero.

8. The temperature compensated package according to claim 1, wherein said clips are sectionalized and wherein each section has a clip section thermal expansion coefficient.

9. The temperature compensated package according to claim 1, wherein a temperature range of each said thermal expansion coefficient M1, M2 and M3 is within a linear range.

10. The temperature compensated package according to claim 1, wherein a temperature range exceeds a linear range of said thermal expansion coefficient M1, M2 and M3, and wherein higher order coefficients are used.

11. The temperature compensated package according to claim 1, wherein said clips are arranged in an azimuthal orientation according to a cut of said crystal to minimize a force frequency effect.

12. The temperature compensated package according to claim 1, wherein said clips have a thermal expansion coefficient such that a combined expansion coefficient of said clips and said substrate are matched to a thermal expansion coefficient of said resonator.

13. The temperature compensated package according to claim 1, wherein a number of said at least two clips are selected from the group comprising 2, 3, and 4.

14. A method for manufacturing a temperature compensated resonator structure, comprising the steps of:
forming a substantially planar base with a base material having a thermal expansion coefficient M₁;
forming a substantially planar resonator with a resonator material having a thermal expansion coefficient M₂;
forming at least two clips with a clip material having a thermal expansion coefficient M₃;
calculating a stress-free structure based on said thermal expansion coefficient M1, M2 and M3, a length of said resonator and a placement of said clip onto said base; and
affixing said clips between said resonator and said base.

15. The method of manufacturing a temperature compensated resonator structure according to claim 14, wherein said step of calculating is by the formula L₁=L₃ (M₃−M₂)/(M₁−M₂), wherein L3 is a radius of said resonator and L1 represents the placement of said clips onto said base.

16. The method of manufacturing a temperature compensated resonator structure according to claim 14, further comprising the step of positioning said clips according to an azimuthal orientation of a cut of said crystal to minimize a force frequency effect.

17. A thermal stress-free mounting structure, comprising:
a base element having a base thermal expansion coefficient M₁;
a substantially planar resonator having a resonator thermal expansion coefficient M₂, wherein L₃ is an approximate distance from a midpoint of said resonator to an outer edge of said resonator;
at least two clips each having a clip thermal expansion coefficient M₃, wherein said clips are coupled to said resonator at said outer edge and coupled to said base at a base connection; and
a means for calculating said stress-free structure, wherein said means comprises processing according to said M1, M₂, M₃, L₃ and placement of said clips on said base.

18. The temperature compensated package according to claim 17, wherein said clips are arranged in an azimuthal orientation according to a cut of said crystal to minimize a force frequency effect.
